(19) United States
(12) Patent Application Publication
(10) Pub. No.: US 2024/0027301 A1
(43) Pub. Date: Jan. 25, 2024

(54) Method and Aircraft for Monitoring Operational States and for Determining Outage Probabilities of Current-Carrying Line Systems

(71) Applicant: Knut Wagner, Brandenburg an der Havel (DE)

(72) Inventor: Knut Wagner, Brandenburg an der Havel (DE)

(21) Appl. No.: 18/042,038

(22) PCT Filed: Aug. 19, 2021
(86) PCT No.: PCT/EP2021/073011

§ 371 Date: Feb. 17, 2023

(30) Foreign Application Priority Data
Aug. 20, 2020 (DE) 10 2020 210 622.3

(51) Int. Cl. G01M 11/08; G01R 31/08

(52) U.S. Cl. CPC G01M 11/081; G01R 31/085

(57) ABSTRACT

A method for monitoring operational states and for determining outage probabilities of overhead power line systems from the air using an aircraft 1, and an aircraft provided to this end are described. To this end, the aircraft 1 in the form of a helicopter is equipped with a sensor system 14 for measuring physical properties of the overhead power line systems with high-resolution digital cameras 13 for image data and with a high-resolution laser scanning system 12 for detecting ambient conditions. The sensor system 14, the digital cameras 13 and the laser scanning system 12 are coupled to satellite navigation systems, apart from GPS, with the detected data being assigned to one another and correlated with one another in relation to both space and time. Monitoring is implemented by way of a single fly-past using the aircraft 1 on the basis of a specified flight profile, and the determined data are supplied to a processing unit which, following an appropriate evaluation, directly indicates or outputs necessary repairs and/or maintenance recommendations on an output unit.

The invention relates to a method and an aircraft for monitoring operational states and for determining outage probabilities of current-carrying line systems in the form of overhead power line systems. This method takes place from the air using an aircraft in the form of a rotary wing aircraft, in particular a helicopter, using which pylons, lines, and substations, including their accessories, can be monitored. In the scope of this invention, a helicopter is understood in the broadest meaning as a rotary wing aircraft and also an aircraft having vertical takeoff capability, using which hovering is possible.

Monitoring methods and aircraft for carrying out the method and for determining physical properties are known.

The use of aircraft to carry out monitoring actions of the states of aboveground current-carrying line systems, i.e., overhead power line systems in the form of power lines, from the air is not only relatively costly. Aircraft also have the disadvantage that for as many measuring tasks as possible, the additional load required for this purpose of the numerous measuring devices for carrying out the large number of measurements is restricted by the maximum additional load of an aircraft, however. Therefore, the measuring tasks are restricted to the required minimum in terms of a compromise. Therefore, monitoring actions have heretofore always still been carried out from the ground by persons pacing off the line systems or by driving along the line systems in corresponding vehicles. The disadvantage of such systems is that inspections carried out in this way require a very long time. Electrical energy is increasingly implemented over longer distances, so that an inspection by traveling along is promising only to a restricted extent even by using ground vehicles.

Typically, monitoring of aboveground and also underground current-carrying lines has taken place for many years by flying over them with, for example, a helicopter. In addition to the pilot, who flies along a route specified by the energy supplier, which is typically made available to the pilot in paper form, an employee of the energy supplier operating the overhead power lines trained for such tasks is also on board. Visual observations are made here and generally accordingly entered manually in provided documents, so that the items of information obtained can be evaluated accordingly later on the basis of the route plan flown, in order to be able to perform repairs or other maintenance measures. The visually recognized faults are entered in these lists after the flight, which often also has to take place in multiple stages with corresponding overnights at various locations because of the length of the overhead power lines or the underground power lines. In this case, for example, Excel tables are used and stored in each case as a PDF file. A so-called handover report thus obtained is provided in this case to the customers, in this case the energy supplier. Although increasingly more measuring technology can be used on board, in most inspection flights carried out up to this point, a separate computer for tasks other than the storage of primarily visually obtained data has not been provided in the helicopter used. These traditional systems or methods for monitoring the power lines and in particular overhead power lines in this case therefore in no way conform to increasingly higher demands for permanent energy supply that is as free from outages as possible.

As is known to the applicant, transferring the routes of the overhead lines to be flown to the pilots in paper form is most widespread for the inspection of overhead power lines by means of a helicopter, wherein the actual inspection of the overhead power lines during the route is only carried out visually by accompanying correspondingly trained persons, thermal cameras are additionally in use, however. The data obtained are entered by the accompanying additional person in a log and provided as a result of the flight to the energy supply company, at which corresponding evaluations are established about repairs or maintenance tasks to be undertaken. Work is thus substantially performed on the basis of manually prepared logs in paper form or in the form of calculation tables. After corresponding evaluation, for example, in special meetings with all participating parties, in general supplementary flights are agreed upon or the repair and maintenance tasks to be carried out are established and initiated accordingly. A similar procedure is used with underground power lines, wherein in this case visual fault or defect recognition plays a rather subordinate role.

The inspections of energy line systems are of enormous importance, since damage-related outages can result in the interruption of the power supply in diverse areas and thus in supply bottlenecks, which can even lead to life-threatening conditions for humans, for example, an interruption of the power supply in hospitals and also the supply of computer-implemented controllers of devices, procedures, and processes, which pervade nearly all areas of human life nowadays. In principle, the power supply has to ensure security of supply for the population and economy. In addition, the interruption of power supply in larger areas can also result in significant problems with a high potential risk in power plants because the power generated there has not been purchased. It is therefore of enormous importance for maintaining the complete infrastructure of the national economies, in particular for the strategically important infrastructure, to have such supply systems function at 100%. The reliability and dependability of the monitoring systems plays a central role here in the context of the so-called performance security.

WO 2012/087 387 A2 describes thermal measurements on overhead lines, for example, from a vehicle or aircraft, from which laser scanning data are recorded, by means of which three-dimensional ground structures and other structures including distance measurements of the current-carrying lines to the vegetation are carried out. By means of the scanning, an open field representation in the surroundings of an overhead line is thus carried out. Exclusively the detection of damage on the transmission line is the focus when using a thermal imaging camera. A direct search for damage to the overhead line system, which obviously also includes the pylons and insulators, as well as optical image data acquisition are not described, nor is the detection of damage specifically to pylons and insulators. This known method does not meet the requirements for efficient and comprehensive data acquisition with moderate expenditure for overflights.

U.S. Pat. No. 4,818,990 describes a monitoring system using a remote control drone. Using this known drone, aboveground lines are merely flown over, wherein field surveys are not carried out. The flights over the aboveground lines described in this known system also only enable at most very restricted monitoring of the phase conductors. Multiple overflights each using different measuring technology possibly have to be carried out, which precludes efficient usage of aircraft. U.S. Pat. No. 4,818,990 does describe that a flight control computer is provided, that electronic sensors determine the additional load for an aircraft, and that electromagnetic and electrostatic field sensors, acoustic corona sensors and ultraviolet sensors, and also infrared thermal images and video cameras can be used, however, all items of information are not location-related and are not coupled to one another, so that large data volumes required for high reliability of the results cannot be processed. The field surveys carried out supply a statement about the necessity, for example, of suppressing plant growth in the direction of the lines. A compilation of all obtained data and automatic evaluation with output of outage probabilities and required repairs and elimination of potential imperfections is not described. The essential disadvantage of the known system is that the obtained data have to be transferred from the drone to an accompanying ground vehicle, since the additional load capacity for the drone is very restricted.

A method for status monitoring of overhead power lines is described in US 2020/0074176 A1. Cameras are described in the known system, however, they are fixedly installed and are not pivotable. They do not achieve the required resolution of less than a few centimeters, which would be necessary for the measurement of beginning surface changes. Further sensors for points possibly endangering the system are used only for acquiring overview data. In general, the aircraft flies over the line system in this known system, however, flying in the area of the phase conductors, i.e., flying adjacent to the phase conductors, is neither described nor is it possible, due to the orientation of the cameras only downward. Rather, to achieve a reliable amount of data and data accuracy with required assistance from the ground, whether using a vehicle or using a ground station located in the vicinity of the aircraft, at least one second flight in the opposite direction to the first flight and recording direction is required. The known method does suggest evaluating the obtained data automatically by means of suitable software, however, for this purpose the data are necessarily transferred to an accompanying vehicle, on which the corresponding computer technology is arranged. A helicopter could be equipped with multiple cameras for this purpose, for example, to completely acquire a pylon in images. However, this has proven to be disadvantageous because of the limited additional load of the required hardware in a helicopter, and all the more so in a drone. For this reason, working with at least two vehicles is proposed, one vehicle which has a laser scanner and an overview camera, and a second aircraft or a second ground vehicle, on which or in which a camera is arranged for detailed image recordings. Only when the overview camera is omitted is it possible to use laser scanning and a camera supplying images of details for the image data in a helicopter. The basic orientation for the method described in US 2020/0074176 A1 is the use of two vehicles, i.e., in case of a helicopter, at least two flights over an overhead power line system would be carried out, namely one aircraft by means of which initially only overview data are obtained, and a second aircraft in which a camera is arranged for image recording of details.

A data acquisition system is described in U.S. Pat. No. 7,298,869 B1, which is preferably used in an aircraft. Concealed or underground anomalies are to be identified using the data acquisition system and filtered in such a way that a three-dimensional digital image of the overflown surface is achieved. The system is operated by the pilot, wherein satellite navigation systems only have to be carried out for chronological and position data assignment. In principle, the pilot has to intervene in the measurement data acquisition. Aboveground structures such as overhead power line systems are not described. Although GPS data are used for the known system, and a laser scanning system is used for underground pipeline monitoring actions, a comprehensive measured value acquisition system which implements and processes a high data volume is not possible for the simple reason that an ultralight aircraft is used as the aircraft, in which the additional load of measuring technology is very limited from the outset with respect to the weight. The known data acquisition system is used to prepare items of three-dimensional information about the topography of the Earth's surface, wherein the presence of two magnetometers indicates lines arranged underground. In principle, the aircraft has to be coupled to earthbound or water-bound vehicles in order to obtain reliable items of information. To acquire anomalies of lines laid underground, flights are taken over their area at constant height (see level). The acquisition of structures such as overhead power lines, their current-carrying lines, and elements fastened thereon or connected thereto is not described in this document of the prior art.

A system and a method for obtaining and processing physical data are in turn described in US 2005/0007450 A1, which data are acquired by means of various acquisition devices that can be mounted on a vehicle, for example, also a helicopter. The data acquisition system is provided to depict ground-based objects including power lines, for example, by means of a helicopter, which flies along the overhead power lines and in which data acquisition devices are housed. Location coordinates are assigned to the obtained data using the GPS system. Defects on lines and elements attached thereon or connected thereto are also obtained, but the quality and level of detail of the obtained measurement data are not sufficient to determine detailed maintenance or repair instructions with accurate location specification. The known data acquisition system operates using so-called NVOF sensors, which are only used to record defined points with narrow observation angle. In addition, so-called LIDAR/LADAR image processing devices are used, which are utilized for distance measurement, but which only enable a limited number of points per acquired square meter, for example, 25 points per square meter. These systems are required for a high and dense data stream of, for example, 1500 points per square meter. The GPS system is also not suitable to this extent to ensure the corresponding data density with respect to a location and/or orientation assignment. An indication of obtaining all required data within a single flight is not mentioned in this known system. There is no indication that inspection recommendations and/or repair recommendations are identified and output.

A drone is described in US 2019/0364387 A1, by means of which data of defects on ground-based systems, for example power lines, are ascertained. This known system has the disadvantage that the use of drones is prescribed as mandatory, which from the outset restricts the additional load, on the one hand, and the range, on the other hand. The required items of information about the status of the overhead power line systems can be obtained without additional personnel or the use thereof only with large and dense data streams, which are required for exact determination of damage on overhead power lines including repair recommendations and maintenance recommendations specified precisely in location. The range of the drone is specified, for example, as only 20 km. Since high-voltage overhead lines often extend over hundreds of kilometers, the use of drones is only practical and possible in the limited local surroundings. Above all, due to the limited additional load, it is recommended that power lines to be monitored be flown over multiple times, for example, to obtain correspondingly accurate and reliable data. Furthermore, the data ascertainable only to a limited extent using a drone require subsequent evaluation by a human worker.

And, finally, a control system for autonomously flying drones is described in DE 10 2015 013 550 A1. The described subject matter of this known control system is directed to using the data arising during the overflight for assistance with respect to the evaluation. The restricted possible amount of data then also only supplies a first assessment of the status of an inspected object and only a first classification. A laser scanning system enabling a high resolution, an output of inspection recommendations and outage probabilities, a correlation of the data with respect to location and time are not described, rather it is indicated that multiple overflights are required using flying drones, irrespective of the limited range of such flying drones.

In contrast, the object of the invention is to perform the essential measuring tasks for comprehensive monitoring of operating states of overhead power line systems, i.e., power lines, by means of only a single overflight by means of a manned aircraft, which is equipped with measuring technology required for this purpose, so that high-resolution images of possible damage locations with respect to the structures of the terrain and also the structures of the overhead power line to be monitored can be obtained cost-effectively by means of this measuring system. Conditions for the respective measurement are to be selected here so that normally exclusionary flight conditions for different measuring tasks may be matched with one another and all measuring tasks can be fulfilled reliably with only a single overflight at, for example, a height optimum for all measuring tasks at one velocity. In addition, the required preparation of control points for the assignment of laser scanning data, as required in the prior art, can be avoided. Improvements of the ecological balance are to be achieved to a significant extent by only a single overflight, for example CO₂ savings and the reduction of other harmful influences on the environment.

This object is achieved by a method having the features according to claim 1 and by an aircraft having the features according to claim 16. Expedient refinements are defined in the respective dependent claims.

The method according to the invention is provided for monitoring operating states, line structure, line safety, and for determining outage probabilities of overhead power line systems, i.e., of aboveground power lines. Line structure is understood here as the structural embodiment of the systems to be monitored with respect to, for example, cables, plastic-sheathed cables, pylons, insulators, crossbeams, transformers, substations, security systems, markings, etc. The monitoring takes place from the air using an aircraft. The aircraft used for carrying out the method in the form of a helicopter has a sensor system, which acquires data representing physical properties of the systems to be monitored, i.e., overhead power line systems, at least one high-resolution digital camera for image data of the vegetation and buildings present at and around the overhead power line systems and mobile structures, such as construction devices, and a high-resolution laser scanner for an acquisition of data on the environmental conditions of the overhead power line systems. High-resolution is to be understood here as a system having in the range of approximately 100 to 1500 pixels/m². This represents comprehensive equipment of the aircraft carrying out the monitoring of operating states, because in this way not only damage to the systems to be monitored, but also beginning worsening of states on the lines, insulators, or other parts of the systems to be monitored can be preventively determined, and assigned specifically and accurately with respect to location. In addition, it is possible to also incorporate environmental conditions, which can also result in an outage of the energy supply if, for example, tree or shrubbery growth reaches the area of the current-carrying lines or if, for example, damage has occurred on the pylons supporting the current-carrying lines, for example, also corrosion-related beginning damage. The data obtained for this purpose are input into a processing unit and compared therein to growth models of the vegetation saved in databases and also taken into consideration for the output of repair and maintenance recommendations.

To perform corresponding assignment of the data obtained using the various data acquisition systems, the sensor system, preferably also comprising position sensors, the digital camera, and the laser scanner are coupled to one another and also to satellite navigation systems, except for GPS. Accurate assignment and accurate locations of existing or beginning damage on the systems to be monitored may thus be determined, due to which corresponding repair and/or maintenance recommendations can be output, for example, to the energy supplier without manually determined data previously having to be entered in lists beforehand. The acquired data can thus be assigned to one another with respect to position and also time and correlated with one another. According to the invention, the aircraft determines, on the basis of a predetermined flight profile in only one single overflight of the overhead power line system, all data acquirable and required using the provided measuring technology, which are necessary to output maintenance and/or repair recommendations for individual elements, sections, or areas of the systems to be monitored with a high level of detail. A high data density is provided and required for this purpose. The determined data are supplied to the processing unit, in which, on the basis of a comparison to, for example, setpoint states of the systems to be monitored, for example, growth models of the vegetation which are stored in the databases, required repairs and/or maintenance actions, recommendations, and also outage probabilities in the case of beginning damage are determined and output at an output unit. The output unit can preferably be an electronic display device.

The sensor system is preferably designed so that thermal measurements such as ultraviolet and infrared measurements can also be carried out by means of thermal cameras, thermal sensors, and/or thermal scanners. It is possible using these measurements, for example, to determine defects on current-carrying parts which have not yet resulted in total outage, but have already resulted in worsening of the physical, current-carrying properties.

The repair and/or maintenance recommendations and/or outage probabilities and/or safety recommendations determined in the processing unit, which are saved as a function of the determined data in the database, are preferably input in this database and also used for subsequent comparisons, so that a self-learning system, so to speak, is provided by the running operation.

The high-resolution digital camera preferably has a minimum resolution of 25-350 megapixels and an image sensor of at least 24×36 mm or at least a medium-format or full-format sensor. To obtain high-precision data by means of the digital camera, this high-resolution digital camera has a harmonizing double mechanical or electronic or mechanical-electronic coupled image stabilization in each case in the camera and in the lens. Therefore, even in the event of turbulent flight, high-resolution photos that can be evaluated in detail can be transferred into the evaluation system by means of the digital camera. The sensor system is preferably also fastened in a stabilizing manner.

The essential advantage of the invention is above all that the multiple overflights existing in the prior art are unified with one another to form a single flight, i.e., single overflight, and that the technology used for data determination can be combined and coupled with one another. The visual inspection methods used in known overflights are automated according to the invention by the development of a corresponding flight profile. By means of a computer located on board, in which the data obtained from the respective measurement systems are linked to one another, the data of three different overflights which are otherwise required can be evaluated accordingly in the case of only the single overflight in reality. The evaluation of the obtained data, which are stored in the database, provides the foundation of a corresponding evaluation, assessment, and description of the work processes to be carried out for repair or maintenance or the nature of the continuous maintenance measures on the overhead lines, on the one hand, and, on the other hand, also forms the foundation that the measures carried out are monitored as to whether the output monitoring program or the output maintenance or repair recommendations have also been carried out in their entirety. In this respect too, it is important that the data obtained by the overflight are updated in the system again, so that the list of repair and inspection recommendations of the work processes required for repair can be specified in detail and the executions thereof can be checked.

Because the various inspection and measuring tasks are combined so that they supply all required data and items of information in their entirety in a single overflight, a significant efficiency increase is achieved over the previously known methods, in which multiple overflights possibly using multiple aircraft are required. An appropriately trained technician of the energy supplier, for example for monitoring the measurements performed during the overflight, and a technician for operating and/or monitoring and/or adjusting and focusing the measuring and recording devices, i.e., the sensor system, the camera, and the high-resolution laser scanning system (high-resolution LIDAR system), are preferably located on board the aircraft, i.e., the helicopter.

The monitoring systems for the sensor system and the high-resolution LIDAR system are preferably installed in the cabin of the helicopter. In addition, a workspace for the trained technician having an appropriate worktable, the computer technology, and the digital camera, which is either automatic or else handheld, and is preferably mirrorless, are additionally installed.

As an essential basic requirement for very highly detailed recordings by the camera, which contain a large volume of information data, the camera has a resolution of at least 25 to at most 350 megapixels. However, equipping the digital camera with harmonizing double image stabilization for both the camera and for the lens, specifically mechanically or electrically or electro-mechanically, is decisive for the quality of the recording of faults, deficiencies, or diverse events to be monitored by the energy supplier. The digital camera preferably has autofocusing (AF) of <0.11 seconds in the phase AF mode. As minimum properties, this digital camera preferably has a sensor having at least 24×36 mm or at least a medium-format or full-format sensor. In addition, the camera preferably has a WLAN, Bluetooth, or NFC conductivity interface. This is required depending on the usage location and incorporation of the digital camera in the overall measurement system for the overall monitoring. The repair and/or maintenance measures achieved on the basis of the measurements and the obtained data are output in detail, so that, for example, for a component to be repaired, even the work expenditure or the expenditure for the maintenance are defined very accurately. After repair is completed, follow-up inspection of the actually executed work on the line systems must of course be performed. This can be carried out in a conventional manner by work meetings with the customer. Of course, this can also be performed via corresponding data comparisons of a previously determined damage situation and after completed repair with the actually existing situation.

It is often also necessary, in particular in the case of overhead power lines, to monitor current fluctuations. These are incorporated into the overall data determination and are also used for the correct assessment of the state of the overhead power line. These data are also collected and recorded in the single overflight and added to the other data and correlated accordingly therewith. In particular, this applies to damage which have a direct influence on a fluctuation of the power supply or the current flow in a respective line.

In the method according to the invention, data storage can preferably either take place completely in the additional computer located on board, or a data transmission takes place to a ground station or to the energy supplier itself, preferably as a live transmission by means of satellite telephone or mobile radio. If a data transmission takes place to the energy supplier or customer, this preferably also includes all recognized faults or deficiencies with corresponding position data and image data in a linked manner, wherein a ranking with respect to the severity of an event is preferably contained in the processing unit. The energy supplier thus immediately receives, preferably at his workstation in his company, direct items of information about which repairs have to be carried out where and at what expense, with which manpower and technology, expediently before an outage of the power supply occurs and/or the line security is endangered. Above all, the prophylactic elimination of imminent damage according to the invention ensures a reliable power supply.

Preferably, the laser scanner, the camera or the cameras, and the sensor system are coupled to a universal measurement antenna, by means of which the combined signals of the satellite navigation system are received. This is followed by splitting of the combined signals into signal data required for a respective processing process. For example, a corresponding satellite navigation system can be divided, inter alia, into a so-called L1 and L2 signal or into the required signal splitting or can be obtained from the existing signal combination. The normal transmission then takes place as the L1 signal, while the channel provided for L2, as a transmission range primarily used by the military, can also be incorporated in the data acquisition and transmission with the appropriate permission and agreement. It is important for comprehensive data acquisition and processing of the data coupled to one another that the entire sensor system, the laser scanning system, and also the camera or cameras use the same data of a single measurement antenna. If a single container is used for the sensor system, for the laser scanning system, and the cameras, it is ensured that all three base systems use the same inertial navigation unit or position sensor unit, which corresponds continuously with the satellite signals in the computer system. The installed software simultaneously controls in the free mode the complete sensor system for complete acquisition of all deficiencies, faults, and events. It also readjusts automatically to guarantee the highest possible measurement accuracy at all times.

For particularly stringent demands on the image data, special cameras can be used, which have an oversized sensor that consists of multiple medium-image or full-image sensors combined to form a unit.

For reasons of high accuracy of the obtained data, the high-resolution laser scanner acquires the data in the 360° full circle all around in the vertical and thus generates a high-resolution 3D depiction of the current-carrying or material-carrying infrastructure, with an accuracy in the millimeter range. These data are also coupled to the sensor system and the cameras. The image data are preferably generated using four digital cameras, which are attached accordingly on the aircraft so that image data can be recorded in the flight direction diagonally to the front, to the rear, and once each downward in the direction toward the ground. Due to the assistance by the digital cameras, accuracies with respect to the data resolution for determining the actual distances or minimum distances of, for example, vegetation, buildings, accumulations, other crossing overhead lines, terrain structures, representation of the cables of the overhead lines, changes in the structural integrity of the overall architecture of an overhead line including transformers or substations or of power-generating or voltage-converting infrastructure with an accuracy of up to 0.7 cm per pixel are achieved.

For data acquisition for the monitoring of the operating states of the overhead power line system, the aircraft preferably flies at a flight speed in the range of 0 to 60 km/h. It is thus clear that there are overlap areas for different monitoring tasks, within which both tasks can possibly be fulfilled simultaneously. One essential advantage of the invention is, among other things, that in accordance with the selected flight speed, for the systems to be monitored, all measuring and data acquisition tasks can be obtained using the same flight speed during the same overflight and can even be processed on location in the helicopter or possibly also in a computing center on the ground. Of course, the flight speed can be varied depending on the required parameters, specifically in the respective specified range. The flight speed can also be changed during the respective overflight or inspection for the purpose of a closer visual inspection by the accompanying person, i.e., the trained technician, and also, for example, for more accurate detection of infrared, thermal, and corona anomalies. A variable flight speed and a sometimes-required change of the side to be observed using the aircraft is necessary for changing monitoring conditions and can be readily implemented using the system, without further overflights being necessary.

The aircraft preferably flies at the height of the overhead power line and laterally to its course direction at a distance of 1 to 50 m. This has the advantage that it is possible to fly quite close to the systems to be inspected, so that the data accuracy can be increased further. With observation of the rules for work on or in the vicinity of overhead lines and power-distributing and voltage-converting infrastructure, the minimum distance to be maintained is 1 m for moderate voltage, and usually at least 5 m for high voltage (>60 to 200 kV) and ultrahigh voltage (>200 kV).

Due to the permanent recording of the laser data and the automatic assignment of the data sequence without displacement or without a data offset, it is possible during the flight, with all systems switched on and also the visually inspecting technician on board, for the position at the overhead power line to be monitored to be changed arbitrarily, so that deficiencies, faults, and corresponding states on the lines or the entire structure of the lines can be not only clearly established, but also clearly assigned locally. The method according to the invention is thus extremely variable. The aircraft, i.e., the helicopter, implementing the method does not have to be refitted, and all measuring tasks which are relevant for a possible repair or maintenance of the system to be monitored can be carried out without the helicopter having to be refitted.

The aircraft, above all in the case that, for example, foundations of pylons are to be inspected for operating states and outage probabilities, preferably additionally has a radar system, which is matched in a similar manner with the other measuring and monitoring systems for comprehensive and locally clearly assigned evaluation and is connected to them with respect to data and signals.

A measuring apparatus is preferably integrated in the helicopter used for carrying out the method, to which a further sensor system is connected for detecting faults and/or defects on the current-carrying overhead power line systems causing disturbances in the electromagnetic field. The sensor system for the current-carrying lines thus feeds the measurement apparatus with the disturbances characterizing the fluctuations in the electromagnetic field.

A selective radiation meter is preferably used for this purpose, in order to measure these fluctuations of the electromagnetic fields characterizing the disturbances.

The faults and/or defects are preferably measured using thermal, IR, corona, or daylight sensors or thermal scanners, wherein more preferably the disturbances and/or defects on the overhead power line systems are acquired as disturbances or changes in the electromagnetic field by means of antennas or antenna bundles and also recorded. A disturbance signal is automatically tracked in the horizontal and/or vertical direction by means of the antennas or antenna bundles in this case.

More preferably, the disturbances or changes in the electromagnetic field, which are ultimately caused by defects or faults on the line system, can be made audible using the measuring apparatus and can also be made visible on an imaging element. It is thus possible that acquired disturbances can be displayed directly on corresponding imaging elements, can be processed accordingly in a computing unit, and are transferable into a measurement log, from which the disturbances can be provided not only designated, but also with a corresponding assignment of the location of their occurrence and thus a faster elimination of these disturbances to the responsible employees evaluating such a measurement log.

Ultimately, the additional sensor system which feeds the measurement apparatus is to be integrated into the aircraft in order to acquire additional sources of fault and to increase the accuracy of the recognition of faults on power lines in the visually nonvisible spectrum of the measured wavelengths of the signals.

Anywhere where electricity is generated, transported, and used, electrical and magnetic fields arise on the current-carrying parts or around them. The higher the amperage and the voltage is and the lower the distance is of the measuring device or the sensor system from the current-carrying elements, the greater are the corresponding field strengths. The greatest or strongest stresses occur in the area of the power supply in direct proximity to transformer stations or substations and at moderate, high, and ultrahigh voltage lines. With respect to the measurement of electromagnetic or electrical and magnetic fields, these experience fluctuations in operation of the current-carrying facilities, when worsening quality, defects, or even imperfections are present in the facilities.

With the measuring technology used, the transmitted AC voltage and the amounts of current conducted through the line are also measured in consideration of the frequency. The determination of these measurement data is used to determine faults or deficiencies of the power transport facilities, which ultimately result in reductions of their efficiencies and additional losses. It is possible to make the disturbances or faults visible by way of UV cameras (corona) and/or IR cameras. These faults from the nonvisible range are thus visually represented in the visible range and can thus be documented. It is also possible using corresponding units capable of processing to make these fluctuations of the electromagnetic fields audible. The intensity of a measured signal decreases with increasing distance to power lines, i.e., the current-carrying conductor cables, wherein the measurement signals can additionally be differently distorted, damped, attenuated, or certainly also amplified under certain conditions.

On the basis of the fundamental physical principle, the electrical field strength decreases with increasing distance from the current-carrying lines. Thus, for example, the field strength can be measured and located at a distance of up to 40 m to the line, specifically at a field strength of 10 microtesla, and at a distance of up to 20 m from the current-carrying lines, the magnetic field has a strength of 10 to 100 microtesla. Of course, electrical fields having a field strength of several thousand volts/meter can be measured significantly more easily and intensively with respect to the measurement signals, which even applies to power lines laid in the ground for the determination of damaged areas, wherein a frequency-selective measurement is preferably performed with respect to the measurement.

Good measurement results are for example also achieved in that a selective radiation meter, for example, is arranged in the aircraft, preferably in combination with a thermal scanner, with a thermal, IR, corona, and/or daylight sensor system. Sources of fault can thus be determined very accurately, for example, for connectors, clamping points, damage to the power-carrying cables, conductor cable passages at insulator suspensions. Even in grounding conductors and optical fibers, it is possible to measure or determine the fluctuations of the electromagnetic waves to find faults at the outer points such as crossbeam tips or pylon tips. Antennas or antenna bundles are used to acquire such disturbances of the electromagnetic field, which are preferably designed as directional antennas and are directed optimally onto the current-carrying lines to be inspected during the inspection flight and in particular to record the disturbances thereon and supply them to a computing unit located on board in the aircraft. The directional characteristic of the antenna or the antenna bundle then permits an accurate identification of the disturbance and thus the determination of the actual damaged area, including the source of fault present there, for example of a component of the power line.

The antennas are preferably provided with automatic direction finding, so that it is possible to track the disturbance signal in the horizontal and in the vertical directions. A breakdown of the direction finding during the inspection flight is thus prevented. More preferably, a coupling with a GNSS (global navigation satellite system) signal is provided, which enables the assignment of the compass direction in the direction finding, the items of time information, and the coordinates for the later evaluation of the data and the assignment of the further generated data from the use of the sensor system and/or from visual inspection. The signals reflecting the respective disturbances are stored accurately in position and height with respect to the layout of the power lines. The signals are also used to assist the damage or faults made visible by the UV camera (corona camera) on the current-carrying lines or the components thereof, so that misinterpretation of damage measured in the UV range can be nearly prevented or significantly reduced. The measurement apparatus preferably acquires, at defects or loose components, damage present there in that the disturbance frequency, which is clear due to crackling or noise, is acquired. In addition, if the faulty point in the power line has, for example, elevated resistances and releases heat in connection therewith, the IR thermal sensor system can preferably make these faulty points visible and confirm a corresponding disturbance frequency source on or at the power line. A so-called backup for the acquired disturbances is thus possible.

Similarly, power lines located in the ground, i.e., underground power lines, can be inspected using these measuring systems preferably arranged in the aircraft or the measuring apparatus provided there. Defective or damaged lines of power lines laid in the ground are checked and determined in a similar manner as described above. Locating the respective fault or the damaged area is thus possible.

If, for example, underground power lines have defects due to earth movements or due to damage from above, the corresponding disturbance frequency is measured using the measuring apparatus, wherein the increased resistance in the current flow generally present at the damaged area is made visible and recorded for assistance by the IR thermal sensor system provided in any case in the aircraft. It is likewise or also additionally possible to use a thermal scanner.

Completely broken lines are also located using the measuring apparatus according to the invention or the aircraft equipped with this measuring apparatus and using the method which is carried out using the aircraft according to the invention, which takes place in that the ground has a different conductivity in the case of a broken line and this is also detectable in a change of the vegetation or surroundings located above it. The determined imperfections can be made audible in a similar manner and can be made visible using an imaging element. All determined data are again preferably automatically coupled to the GNSS signal, i.e., a satellite-supported signal. An exact position and orientation determination of the fault or the imperfection can additionally preferably take place by means of a distance meter and the angle determination of the UV and IR camera. A thermal scanner is preferably used, by means of which a larger angle range and larger wavelength range can be scanned in comparison to conventional thermal cameras. This is advisable above all in the case of power lines laid underground, in the case of which the actual laying location is possibly not known exactly.

The high-resolution LIDAR system preferably used acquires irregularities in the area of the damaged areas due to its high point density in the range of 1500 pixels/m², which are then accordingly well visible and can be documented.

The determined faults or fault states are either already evaluated in the computer-supported unit on board or are stored by means of live transmission via diverse radio-supported transmission options in corresponding computer systems on the ground.

According to a further aspect of the invention, the aircraft used for carrying out the method has a sensor system for acquiring faults, deficiencies, operating states, and material states on overhead power line systems, a plurality of high-resolution digital cameras for image data of the systems, and a high-resolution laser scanning system on and/or in the aircraft. The sensor system, the digital cameras, and the laser scanning system are attached in mounting units, wherein a computer is provided internally in the aircraft, by means of which the three measurement or inspection data obtained from the units are correlated with one another, the data thereof are processed, and corresponding recommendations are determined for required or upcoming repair and/or maintenance actions and probabilities of outage and supplied to an output unit.

The measuring technology preferably has a sensor system having ultraviolet and/or infrared sensors and position sensors, multiple high-resolution digital cameras, preferably mirrorless, having a minimum resolution of 25 to 350 megapixels having mechanical or electrical or electromechanical stabilization of both camera and lens and the high-resolution laser scanner having 360° full circle all around in the vertical. The data obtained are each supplied to the computer and correlated accordingly therein, so that all data are connected to one another and a clear assignment of an event or a case of damage is possible. The sensor system and the laser scanner are preferably coupled to a universal measurement antenna, via which the obtained combined signals of the satellite navigation system are receivable and after reception they are split into signal data required for a respective processing process. The GPS signals are preferably divided into L1 and L2. L1 is predominantly used here for the civil sector, while L2 is normally reserved for the military sector, but can also be used for these objects to be achieved according to the invention here with appropriate agreements or contracts. For the inspection of foundations of pylons, for example, a radar system is preferably additionally installed in the aircraft, by means of which foundations located in the ground can be monitored accordingly in terms of a ground radar.

The aircraft is preferably a manned rotary wing aircraft, in particular a helicopter. By means of the processes running in the computer for the flight control, all required data are acquired, compiled, and evaluated. On the basis of the data, which are compiled and correlated with one another, there is an assessment of the subsequent actual maintenance work on the power lines laid above ground or underground, including their surroundings, wherein the recommendations for such maintenance work can be output immediately and directly. The overhead power line systems also include, of course, the corresponding support, guying, or gantry pylons and substations. By means of the obtained laser scanning data, at a resolution of up to 1500 points or pixels per square meter, the possibility is created of recording the line structure, such as the pylons and the substations, in detail with respect to their condition and dimensions and to determine the distances to the individual assemblies of an overhead power line pylon or of components in substations for the exact computations in the single-digit millimeter range. One essential advantage of this comprehensive recording results from the density of the generated laser points. The entire structure of the overhead lines and the substations or the transformers and the power-generating and voltage-converting infrastructure can thus be rotated and assessed in high-resolution 3D form and 360° in all directions. From the measurement at millimeter accuracy of components of the overhead line and/or of distances to one another and/or pivots, changes of the bending torques of the pylon construction due to environmental influences and/or mechanical influences can be determined. Due to this high resolution of the data, a position determination at millimeter accuracy of the pylon locations is even fundamentally possible. In the scope of the overflight of the overhead lines to be inspected, the sags of the phase conductors at the various exterior temperatures can also be acquired on the basis of the cable temperature measured during the flight by means of an additional infrared or thermal camera or a thermal scanner and evaluated accordingly for the energy supplier. In this temperature measurement, the conductor cable temperature measurement also takes place from the phase conductors extending closest to the ground with the view from the helicopter toward the sky, in order to exclude background temperature variations, which would be present, for example, if the measurement were to take place toward the ground. In contrast, if the measurement is carried out toward the sky or space, there is a high consistency of the temperature radiation from space.

During the inspection of foundations of the pylons of overhead power line systems, the work is preferably carried out with a ground radar, thermal scanners, multispectral scanners, and similar technical devices, wherein these are additionally arranged in or on the aircraft.

The transmission in particular of the image data from the helicopter, for example, to the energy supplier can take place live in this case, so that the inspector of the energy supplier located on the ground can exert direct influence on fault detection. In this respect, the helicopter can fly at points at which faults, damages, or deficiencies have previously been detected. Corresponding ultrasonic sensors and laser distance meters guarantee that a minimum distance of 5 m to the overhead line is maintained. If the data are not evaluated in the onboard computer, but rather sent to a ground station, the route that can be flown using such a helicopter in one overflight can nonetheless be of virtually any length.

In particular to be able to acquire the imperfections and defects on the current-carrying lines during inspection flights, the aircraft according to the invention thus has a further sensor system, which feeds a measuring device or measuring apparatus, by means of which the faults, deficiencies, and/or defects present on the power line, no matter whether it is an overland line or a line laid in the ground, on the current-carrying line systems, which result in corresponding disturbances of the electromagnetic field that are measurable, can be made audible by means of an audio device and/or visible by means of an imaging device. These data are stored in a processing unit, from which an inspection log can then be displayed or printed, directly specifying the faults or defects and the degree of damage, so that corresponding repairs can be initiated and carried out immediately on the basis of an inspection log showing such disturbances.

According to the invention, a novel method and an aircraft are thus provided, which are used for monitoring and coordinating maintenance measures on current-carrying overhead line systems on the basis of comprehensive data obtained in a single overflight.

Further advantages, details, and possible applications of the present invention are explained in more detail in the following drawings. In the drawings:

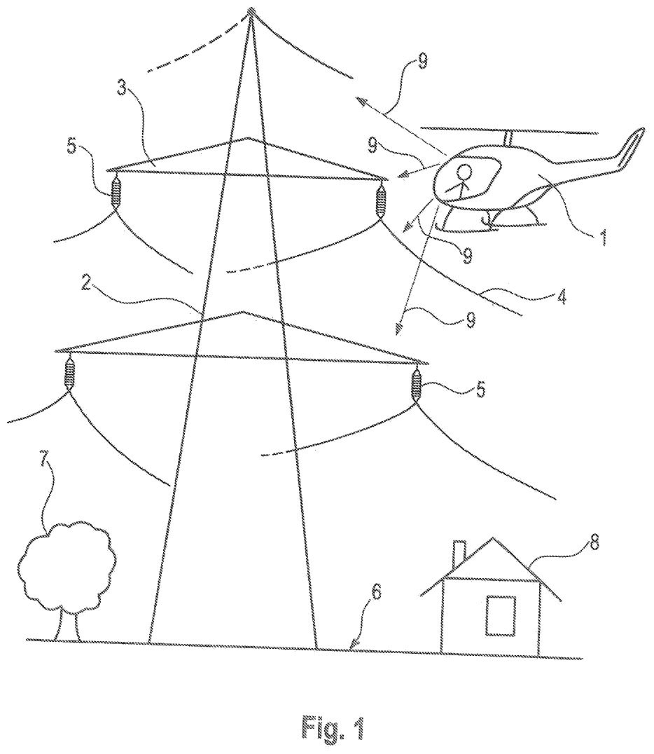

FIG. 1: shows a schematic illustration of a pylon in the terrain for a power line having a helicopter being used for a visually performed inspection according to the prior art;

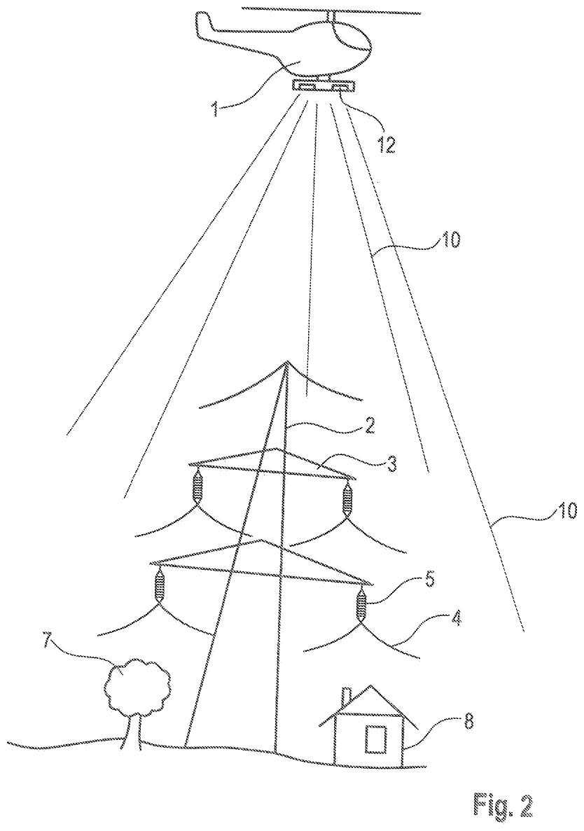

FIG. 2: shows a power pylon in the terrain having a helicopter for carrying out an inspection by means of laser scanning according to the prior art;

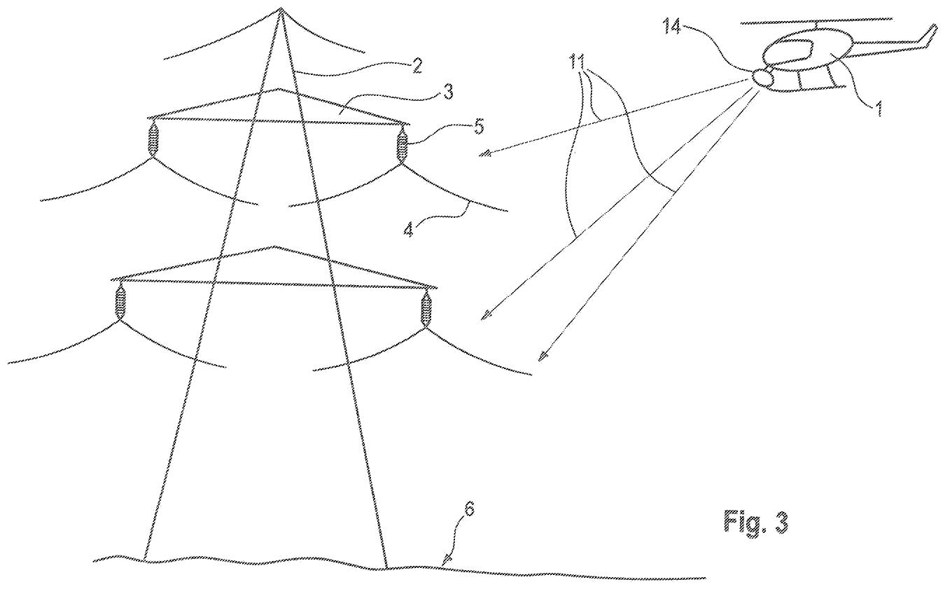

FIG. 3: shows a power pylon in the terrain having a helicopter for inspection by means of a sensor system according to the prior art;

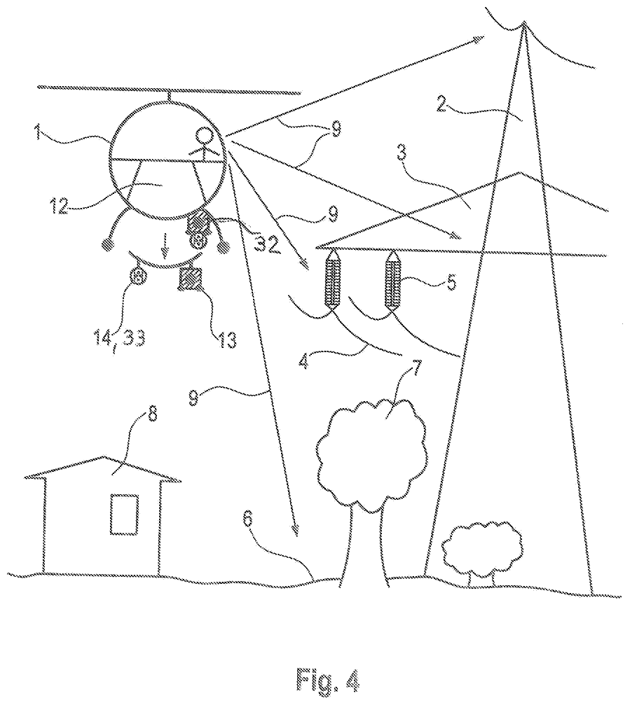

FIG. 4: shows a power pylon in stylized form in the terrain having a helicopter equipped with sensor system, cameras, and laser scanning system for a combined inspection using a single overflight according to the invention;

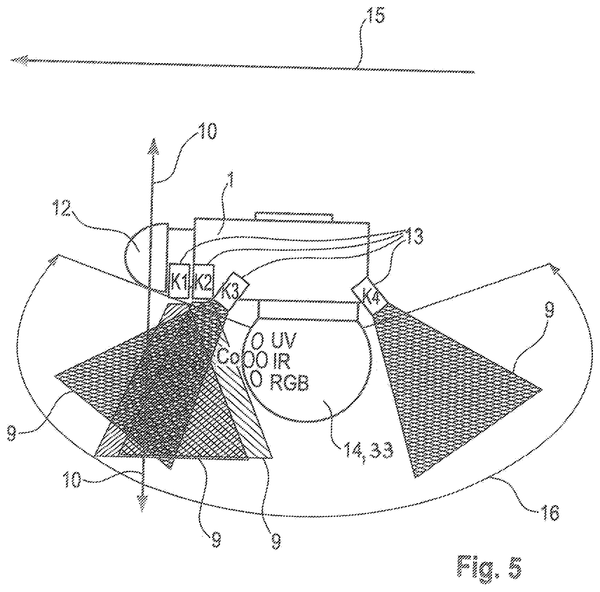

FIG. 5: shows a schematic illustration of an aircraft equipped with a sensor system, multiple high-resolution cameras, and a laser scanning system as a helicopter according to the invention for carrying out the method according to the invention; and

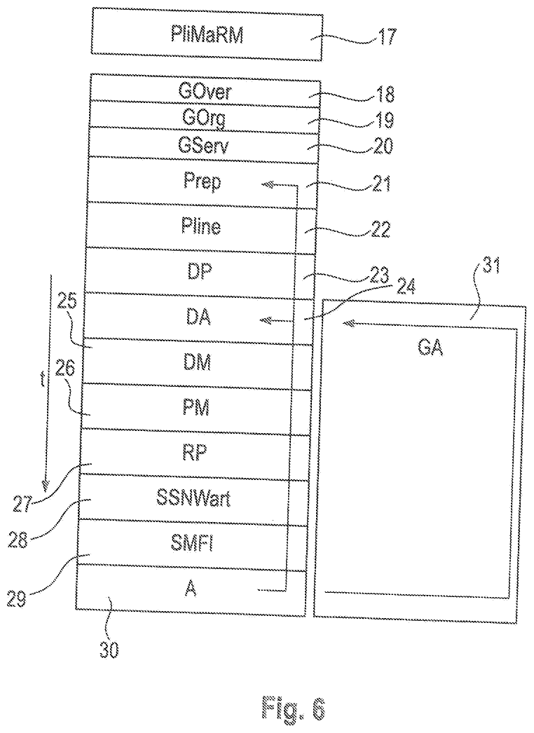

FIG. 6: shows a schematic flow chart for the combined inspection of power lines of an overhead line grid by means of a single overflight according to the invention.

A power pylon 2 for an overhead power line in the terrain is shown in stylized form in FIG. 1, in which a visual inspection implemented by means of a helicopter 1 is being carried out. The visual inspection is carried out in the known manner in that a visual inspection is performed visually by means of cameras (not shown) by means of an aircraft in the form of a helicopter 1 or rotary wing aircraft in the area of power lines 4 fastened on a power pylon 2 at corresponding crossbeams 3 of the power pylon 2 by means of insulators 5, in that corresponding image representations for corresponding measuring and recording devices 9 are carried out by means of multiple cameras. The power pylon 2 is in the open terrain on the ground 6, and the aircraft 1 flies over vegetation 7 and buildings 8 at the height of the crossbeams 3 of the power pylon 2, specifically laterally thereto. In addition to the pilot, an employee (not shown) of the power supply company or a technician contracting with this company is also flying, by whom the cameras are manually operated and various elements such as power pylon, insulation 5, power lines 4, terrain structure 6 including vegetation 7 and buildings 8 are recorded. During the generally visual inspection flights, the accompanying inspector recording the corresponding images has to manually note in a list the locations at which he has made corresponding photos if the cameras are not capable of also saving location-related data at the same time. It is clear from this known visual inspection method that such a special overflight is only carried out to obtain image data.

However, this means that further overflights are required for further data acquisition tasks. A situation known in the prior art is thus shown in FIG. 2, in which a helicopter is equipped with a laser scanning system, specifically in this case with a LIDAR system, and at a significant height above the power pylon 2, performs laser scans of the area of the power pylon 2 in the terrain, incorporating the vegetation 7 and/or possibly existing buildings 8 and of the power pylon 2 itself with its crossbeams 3 and insulators 5 fastened thereon and the power lines 4 supported thereon, in that the laser scanning system is oriented downward and forms a measuring or recording direction 10. The aircraft 1 or the helicopter flies over the power lines at a relatively great height at a speed of 35 to 80 km/h at a height of up to 200 m above the maximum pylon height or the height of the power lines 4. It is apparent from this that in this known system for obtaining laser scanning data, different flight conditions have to be maintained and used during the overflight than are required for the visual inspection by means of the cameras according to FIG. 1, during which the pilot guides the helicopter laterally to crossbeams of the pylons 2, so that the inspector can perform corresponding camera recordings of the status or elements or parts of the overhead power line having damage.

FIG. 3 shows the situation for a further separate overflight of an overhead power line by means of an aircraft 1 in the form of a helicopter 1. The power pylon 2 having its crossbeams 3, on which the insulators 5 are shown, to which the current-carrying lines 4 are attached, is shown in a stylized representation on the ground 6. The helicopter 1 itself is provided with a sensor system 14, which has UV, IR, RGB, thermal, position, and corona sensors. The recording device 11 is shown for the measurement by means of the indicated sensors of the sensor system 14 installed in the aircraft 1. In contrast to carrying out the inspection visually according to FIG. 1, in which, for high-voltage lines, the aircraft 1 flies at a distance of 5 to 15 m laterally to the power pylons 2 and, for low-voltage lines, at a distance of 1.5 m, likewise laterally to the power pylons 2, a distance from the recording element to the overhead power line in the range of 30 to 50 m is provided for carrying out an overflight for the corresponding measurements or recordings by means of the sensor system 14 installed in the aircraft 1, wherein the operating altitude essentially takes place at the same altitude in the area of the upper crossbeams 3. The flight speed is implemented at 25 to 45 km/h for this overflight. The different overflights carried out in FIGS. 1 to 3 for different measuring or recording situations have the result that at least three overflights are required to obtain all necessary data for a comprehensive inspection. This represents an enormously high expenditure and makes correlation of data obtained in the respective overflights with one another significantly more difficult, so that in spite of the relatively high expenditure for additional manual work, for example preparing Excel tables, a correlation of the data obtained using the individual overflights is at most possible only to a very restricted extent. It is clear above all from the different conditions for the respective overflights according to FIGS. 1 to 3 that common conditions hardly exist both with respect to the distances and the flight speeds for the individual measuring or recording data, so that the individual overflights, with their individual measuring tasks and conditions to be complied with for this purpose, fundamentally exclude one another.

In contrast, FIGS. 4 and 5 show the situation for a single overflight carried out for the inspection with incorporation of high-resolution image data, high-resolution laser scans, and a corresponding sensor system (see FIG. 4) as well as an aircraft 1 (see FIG. 5) according to the invention designed having the corresponding measuring and recording devices. The overall data acquisition and data processing system is designed so that significant amounts of data can be processed reliably in a very short time.

The combined inspection overflight according to the invention shown in FIG. 4, of a power line as an overhead line in the terrain, is carried out using an aircraft 1 in the form of a helicopter, in which a high-resolution LIDAR system 12 as a laser scanning system, a sensor system 14, which includes UV, IR, RGB, thermal, position, and/or corona sensors, and multiple high-resolution cameras 13 fastened on various points of the aircraft 1 are provided and combined with one another, which can make digital image data, i.e., recordings, directly downward and also to the front and to the rear in the flight direction. Moreover, it is additionally possible that the accompanying inspector manually records photos of selected points, wherein the cameras or the camera 13 can then be directed toward various points in the measuring/recording direction 9. The sensor system 14 and the camera 13 can also be fastened on the underside of the aircraft 1 here. It is also possible that the sensor system 14 and the camera are fastened at opposite sides on the underside of the helicopter 1. This is shown in FIG. 4 by the indicated bottom area of the helicopter 1 with the arrow which shows the underbody area as a separate part. The helicopter 1 has a measuring apparatus 32 having a further sensor system 47 for measuring imperfections and defects on the current-carrying lines. Disturbances in the electromagnetic field are measured in this case.

The system according to the invention or the method carried out using the aircraft 1 according to the invention are now fundamentally based on all three measuring or recording complexes, i.e., the high-resolution cameras 13, the sensor system 14, and the high-resolution LIDAR system 12, i.e., the laser scanning system, being coupled to one another, so that all data are correlated with one another and a clear spatial orientation and also a position specification are possible. The measuring and recording technology used, in particular the sensor system 14 and the laser scanning system 12, is coupled with the satellite navigation system via a universal measurement antenna, so that the received data for the measuring or recording devices used can be used with correspondingly performed data allocation for the various operational processes.

Substantially automated, combined, and complete monitoring thus takes place of both the operating states and the physical properties and also existing damage or beginning damage, which could possibly result in an outage of the energy supply in future. This determination and compilation of all of the mentioned data and items of information results in prophylactically oriented service and maintenance including required immediate repairs. The system used now processes the data so as to produce specific action recommendations, time ranges by which specific repairs or corrections have to be performed, and passes on these items of information on a display device to the energy supplier or to a company contracted thereby. The data sets including the action recommendations can be printed or passed on electronically to the responsible customers of the overflight company.

The helicopter 1 flies at a speed of 0 to 60 km/h at a distance to obstacles in the range of 0 to 50 m at an operating height of nearly 0, i.e., in the ground area up to the height of the pylons. The measuring or recording technology is now conceived and adapted to one another so that the helicopter 1 can fly at a defined working height, preferably in the area of the respective crossbeams 3 laterally to the overhead power lines and thus laterally to the pylons 2 and can nonetheless reliably fulfill all three fundamental measuring and recording tasks. This was not possible in previously known systems by means of a single overflight. An overflight is understood in conjunction with the underlying subject matter here as an overflight in one direction. This does not mean carrying out the measurements or recordings in an outbound flight and a return flight. An outbound flight and a return flight are generally to be equated to two overflights. Carrying out all three measuring and recording tasks in a single overflight and also housing a data processing unit as a computer having a corresponding processing unit in a single aircraft 1, preferably a helicopter, is not known in the prior art.

FIG. 5 shows an aircraft 1 according to the invention, in which the described complete sensor system 14 for all measuring and recording tasks is unified. The sensor system 14, comprising UV, IR, RGB, thermal, position, and corona sensors, as well as video cameras and the high-resolution LIDAR system are accommodated in a spherical container, which is freely rotatable, i.e., vertically and horizontally rotatable, and is moreover suspended with a full gimbal and gyroscope stabilized. Due to restricted additional load for such an aircraft 1, an essential condition is that all of the measuring technology, the recording device, and also the data processing device are light and small enough that they can all be not only housed without problems in the aircraft 1, but also arranged and oriented so that all measuring and recording tasks can be carried out using the sensor system 14, the cameras 13, and the laser scanning system 12 and that all data obtained via the three mentioned measuring and recording complexes can be correlated with one another and to one another via the simultaneous arrangement of a data processing system inside the aircraft 1. The data can thus provide not only an overall overview about possible service, repairs to be carried out, or existing or developing damage, rather the obtained data are also updated in a corresponding database. A data set which becomes larger is thus formed for future overflights for inspections and service and repairs, which enables accurate, reliable comparison data corresponding to the actual conditions to be obtained from determined data.

The laser scanning system 12, the so-called high-resolution LIDAR system, which carries out a laser scan in the measuring/recording direction 10, is arranged in the front area of the aircraft 1. The aircraft 1 furthermore has four cameras 13 arranged, designated as K1 to K4, which have respective conical image covering areas in the respective recording direction. For this purpose, the cameras K1 and K2 are arranged in the front area of the aircraft 1 and are directed essentially vertically downward in the direction toward the ground 6. The two cameras K3 and K4 are each directed to the front (K3) in the flight direction 15 or to the rear (K4) in the flight direction 15.

A sensor system 14 is arranged on the underside of the aircraft 1, which includes UV, IR, RGB, and at least also corona sensors. The sensors are arranged and pivotable so that a pivot range 16 of the sensor system 14 implements a corresponding measurement coverage in the schematically shown way.

And, finally, a flow chart is shown in FIG. 6, from which the individual components and sequence steps for obtaining data by means of the three measuring or recording devices for comprehensive monitoring of overhead power lines, including a reliability management system, are apparent.

The monitoring and reliability management 17 of overhead power lines (PliMaRM) comprise the following steps or complexes covering the overall system according to the invention. Firstly, a power grid overview (GOver) 18 is prepared. The foundation of the inspections are, for example, items of information for the pilot from the energy supplier issuing the contract, as to which of its grids is to be inspected. For this purpose, initial discussions are held with the energy supplier to define what is expected by the energy supplier as the goal of the inspections.

In the context of so-called power grid organization (GOrg) 19, items of information are compiled with respect to the structure and the organization of the contracting energy supplier, to define direct connection points to the company carrying out the overflight on the orders of the respective energy supplier. A breakdown or an information bundle is defined here and transferred to the company carrying out the overflight, for example, with respect to so-called reporting positions, i.e., the responsible positions at the energy supplier, to which the data obtained from the overflight are to be transmitted. An overview is included here about who receives data from whom. This also includes which corresponding releases have to take place with respect to the data use. A reporting system in the event of serious events is also integrated in this complex, i.e., repairs already urgently required, because of which corresponding releases for carrying out work on overhead lines or in the vicinity of the overhead lines and the substations have to take place and be arranged.

In the scope of the following complex of the power grid maintenance (GServ) 20, an overview is provided about the contracting energy supplier's own grid, in order to be able to make the specification of particular focal points for the inspections. It is included therein whether the inspections have to be carried out only on the core grid or also on lines belonging to the core grid plus specially located grid areas. The specification of carrying out inspections with particularly high density at damage events is additionally included. In particular in the case of the latter, it is necessary that above all these areas of the lines are inspected particularly intensively and with all existing measuring technology, so that the corresponding action recommendations can be output automatically. In the scope of this work complex, it is also provided and necessary to equip the accompanying inspection crew with corresponding powers on the orders of the energy supplier and also to grant the corresponding release or work authorizations for the energy supplier. In the context of a close cooperation between the contracting energy supplier and the company carrying out the overflight, the in-house personnel are trained accordingly for work on or in the vicinity of overhead lines for carrying out the inspection of overhead lines of every voltage level. Such modules are integrated in the data processing system. Incorporated therein are fault recognition or deficiency identification, types of the technology of the individual elements (for example, the type of the pylons, the substations, the transformers, the type of the insulators, the suspensions, the attachment and the type of the connectors, etc.). In terms of effective preparation for the inspection to be carried out, the training of the inspection crew with respect to the structure of the overall energy grid, its functions, the technology used for the respective elements, possible outage scenarios and outage probabilities, and the influences of the energy transport on the population and economy and environment, as well as the influences on the electronics installed in the aircraft, i.e., in the helicopter, are also incorporated. The latter is important above all since depending on the type of inspection, and depending on external influences during the inspection, a negative influence on sensitive electronics in the helicopter above all is to be precluded. The training of the inspection crew also includes the structure of the inspection software used, including its application and possible supplementary modules for further functions and tasks, which are not yet present in the inspection software, of the measurements or inspections carried out. This means that in the case of nonexistent or also possibly presently not available data in preparation and above all also during the overflight, corresponding adaptations of altered conditions can and must be carried out on the software and the evaluation electronics.

In the next step, which is also designated as preparation (“Prep”) 21, inputs are made into the electronic processing unit, i.e., the computer, for the preparation and transmission of the required data of the overhead line grid to be inspected, specifically of the overhead line grid which is to be inspected and monitored, in accordance with the contract of the energy supplier. For this purpose, data relating to the pylon locations, the locations of the transformers or substations, the locations of the transformer stations, the types of the pylons, their structural forms, the various voltage levels, also corresponding ownership assignments and similar things are input, so that during an overflight, the corresponding basis and assignment of the obtained data exist for the grids or grid sections actually in the contract for inspection. If faults or deficiencies or events relating to them are already known, for example from earlier overflights, their severity is specified and also input into the data processing system or determined thereby. The fundamental work expenditure for eliminating these mentioned deficiencies is also specified, which is input in the data processing system and stored there in a memory, so that it forms a corresponding data foundation for future assessments. Overall, in the context of this sequence step, a first assessment of the findings obtained is performed on the basis of assumptions and data available up to this point. This contributes significantly to carrying out the corresponding overflight effectively.

Only after this fundamental preparatory work is the monitoring of the power line (Pline) 22 carried out in the context of the actual flight mission, i.e., the overflight, using the sequence of the inspections resulting accordingly due to the overflight. These include the observation of the overhead lines, the documentation of faults, deficiencies, or events, wherein the assessment of the severity of a specified event is also specified automatically with the aid of the data processing device, i.e., the additional computer located on board.

In accordance with the severity of the event, an immediate report is performed by the processing system in the case of severe deficiencies or events in the form of a transmission and output of images, videos, etc. On the one hand, the energy supplier can thus immediately obtain items of information that, possibly deviating from the overflight sequence performed in step 21, a targeted approach to the location with a deficiency which is to be eliminated immediately is possible, so that with the cooperation of the flight crew or else under its essential responsibility, an immediate intervention can take place. Immediate interventions in terms of avoiding hazardous situations on the ground would be, for example, passing through items of information to appropriate points, for example, stopping construction sites in a safety area of overhead lines, for example, when it is also established that safety distances to be maintained in the pivot range or work range of cranes or diggers are not ensured. Such relevant data are transferred directly via a prior automatic determination live to the contracting energy supplier.

The step of monitoring the overhead power line can take place, as described above, deviating from a predetermined flight profile; however, in general, if severe deficiency events are not present, the overflight is carried out using the flight profile prepared according to step 21. During the overflight, in general the overhead power line is monitored metrologically, by imaging, etc. using all measuring technology installed on board, wherein an assignment of the obtained data to the corresponding locations in the system takes place at any time. The overall data set then contains all items of information to plan repair, service, or component exchange work accordingly, wherein the system is constructed so that such work is transmitted automatically to an output device with respect to the scope and components to be replaced or refurbished, without the need for large meetings with the participating divisions and employees of the energy supplier.

In the next step of the data processing (DP) 23, the further data processing takes place after the inspection flights on the basis of the inspections carried out by the sensor system, the laser scanner, the daylight digital camera, and the visually established defects. During the data processing, the correlation of the data obtained from the individual sensor systems or measuring systems with one another takes place. This includes generating digital height models of the ground profile, specifically on the basis of generated laser data by means of a so-called point cloud either with vegetation and buildings or without vegetation and buildings, and with a very high measurement accuracy. As a result, a 3D model of the entire overhead line technology is created, so that later measurements of distances within the overhead line technology or, for example, deformations of pylons and crossbeams and also other load-related deformations of components on the overhead line systems can be incorporated as the foundation for a comprehensive and detailed and robust and reliable evaluation.

The data analysis (DA) 24 takes place as the next step. In the scope of the data analysis, the obtained data are analyzed, a final judgment takes place in the sense that an expansion of the initial analysis during the inspection is performed, wherein an evaluation of the laser data is performed with inclusion of the following substeps:
a) After the corresponding specifications of the energy supplier commissioning the inspection, the generated point cloud is defined with regard to type of vegetation, growth analysis in the safety area of the overhead line, furthermore with regard to distances of obstacles below and adjacent to the overhead line, to safety distances to the ground with respect to agricultural aspects, for example, the structural heights of agricultural machines.
b) A measurement is carried out of the change of the overhead line technology or the entire line system with respect to deformations, for example torsion, occurring due to external circumstances such as weather, soil displacements, snow load, etc.
c) Furthermore, a computation is carried out of the various load states of the overhead lines at various external temperatures, specifically on the basis of the laser data and the cable temperatures measured in the flight, wherein both measurement results are correlated with one another and related to the respective location relationship.
d) Furthermore, the influence of the vegetation below and adjacent to the overhead lines on the safety of the lines and the influence on the environment are included in the computation.

On the basis of this extensive data bundle, which results from measurement results and computation results and correlation results, the scope of work and the sequence and the material expenditure required for the repair, the required machine expenditure, the number of repair points and the work expenditure of maintenance personnel or service personnel are compiled for all acquired and computed deficiencies, faults, or events and transmitted to an output device on the basis of the data bundle and displayed. In addition, to prepare for the required repair or maintenance work, corresponding contracts for assigning maintenance tasks to external companies are passed on to the output device and output there.

The power grid analysis (GA) 31 is also incorporated in the data analysis 24. For the power grid analysis 31, the obtained data, the contents of knowledge-based databases, the monitoring reports, the status reports, the yearly audit, and the power grid measurement result are used.

On the basis of these further or additional or comprehensive data sources, a power grid recommendation including service recommendations is created by the computation unit, i.e., the provided computer, and transmitted to the output unit. Furthermore, statements on the cost-effectiveness or the efficiencies of the power transport in the monitored grid are also incorporated. On the basis of the various data and data sources, finally a power grid reliability is also transmitted to the output device and output thereby. All existing data, including the knowledge-based data sets present in the databases, are ultimately used to improve the quality of the operation of the power grids, wherein these data can also be used for efficient power grid planning in terms of power grid load predictions.

After the step of data analysis 24, the step definition meeting (DM) 25 follows, which includes a meeting with the contracting energy supply company, in which the obtained and evaluated data are displayed and transferred digitally in the data format desired by the energy supply company. This includes a data transmission into the software systems and computers of the energy supply company.

In the step measure packet (PM) 26, a specification of the service, maintenance, or change measures takes place with corresponding time specifications for the planned completion. The measure recommendations are specified in the final result to be transferred and are based on the entire obtained data bundle.

In the step fault elimination duration or desired time goal (RP) 27, on the basis of the data evaluated and discussed in the meeting by the energy supplier, the data are analyzed, finally specified, and measures are taken which are used to eliminate faults or to reestablish the current carrying in the respective conductors. This represents an important measure for the feedback from the energy supply company to the company carrying out the overflight, by which in close cooperation with one another, the overflight expenditure and thus the cost for the maintenance can be optimized

This is followed by the step of determining the status of the power grid service activities (SSNWart) 28. In the context of this step, the energy supply company informs the company carrying out the overflight about the status of the service and maintenance measures and about the construction—and renovation possibly to be performed—of overhead power lines. For this purpose, the corresponding items of information and the preparation for updating the evaluated data are transferred from the logs in terms of active tracking of measures to be carried out into the computer system at the company carrying out the overflight.

The step of the status of the monitoring flight (SMFI) 29 represents a further step. On the basis of the items of information on the measures to be carried out, which have been exchanged in the prior step between the energy supply company and the company carrying out the overflight, it is specified whether further inspection flights are required on the basis of the obtained results of the prior sequences. This represents a follow-up inspection and can possibly result in a supplementary inspection measure in the form of an additional overflight.

And, finally, in the final step of the entire sequence of the monitoring and reliability management tasks to be carried out of overhead power lines, the audit 30 takes place. In the context of this audit 30, auditing of the energy supply company takes place on the basis of the entire preceding process, including preparing and carrying out repetition overflights possibly to be performed or the inspection of other grid parts, which have not yet been taken into consideration during the first overflight, but are important for the overall assessment. In the context of the audit, a meeting of the participating responsible employees takes place, in which changes of the existing safety and risk management or its expansion or the reimplementation thereof are determined.

One important aspect is the permanent continuation, improvement, or expansion of the qualification of the employees of the company carrying out the overflight and of the energy supplier, including the maintenance personnel, who are possibly provided by external firms, on the basis of the recommendations computed by the processing unit of the computer system and output at the output unit. On the part of the company carrying out the overflight, on the basis of the evaluation of the overall data bundle, proposals are recommended for adapting and improving the entire overhead line technology and additionally adapting the inspection technology. This has the advantage that the existing systems are permanently improved in an automated manner in the context of a feedback loop.

Using the method according to the invention and the aircraft according to the invention, in addition to the significantly more complex and faster data acquisition in comparison to known systems or methods, a significant contribution is made to reducing harmful influences on the environment, such as reducing CO₂ emissions.

### LIST OF REFERENCE NUMERALS

1 aircraft/helicopter/rotary wing aircraft
2 power pylon
3 crossbeam
4 power line
5 insulator
6 ground
7 vegetation
8 building
9 measuring/recording direction of camera
10 measuring/recording direction of LIDAR
11 measuring/recording direction of UV, IR, RGB, THERMAL, CORONA, position sensor
12 LIDAR system, laser scanner/laser scanning system
13 camera
14 sensor system of UV, IR, RGB, THERMAL, CORONA, position sensor
15 flight direction
16 pivot range of sensor system
17 monitoring and reliability management of overhead power lines (PliMaRM)
18 power grid overview (GOver)
19 power grid organization (GOrg)
20 power grid maintenance (GServ)
21 preparation (Prep)
22 monitoring of overhead power line (Pline)
23 data processing (DP)
24 data analysis (DA)
25 definition meeting (DM)
26 measure packet (PM)
27 fault elimination duration/desired time goal (RP)
28 status of the power grid maintenance activities (SSNWart)
29 status of monitoring flight (SMFI)
30 audit (A)
31 power grid analysis (GA)
32 measuring apparatus
33 further sensor system

1. A method for monitoring operating states, line structure, line safety and for determining outage probabilities of overhead power line systems from the air using a manned aircraft, the method comprising:
a) the aircraft is at least equipped with a sensor system for acquiring data representing physical properties of the overhead power line systems, at least with a high-resolution digital camera for image data of the and around the overhead power line systems, and with a high-resolution laser scanning system for acquiring data on environmental conditions, the structure of the terrain, and the conductor structure of the overhead power line systems, which has an accuracy of up to 0.7 cm/pixel;
b) the sensor system, the digital camera, and the laser scanning system are coupled to one another and to satellite navigation systems, distinct from GPS, and use the same data of a single measurement antenna;
c) the acquired data are assigned to one another with respect to position and time and are correlated with one another;
d) the aircraft determines all data including its current fluctuations at one selected, uniform flight speed on the basis of a predetermined flight profile at the height of the overhead power line and laterally to its course direction in only one single overflight of the overhead power line system; and
e) the determined data with respect to damage or defects on the overhead power line systems and/or beginning worsening and/or influences by environmental conditions of the line structure are also determined preventively and are supplied to a processing unit, in which required repairs and/or maintenance recommendations and outage probabilities for individual elements, sections, or areas of the line structure with incorporation of growth models of the vegetation are determined in terms of a self-learning system on the basis of a comparison to states contained in a database stored therein and are output at an output unit.

2. The method as claimed in claim 1, wherein the sensor system carries out temperature measurements, in particular ultraviolet and infrared measurements.

3. The method as claimed in claim 1, wherein the repair and/or maintenance recommendations and/or outage probabilities determined in the processing unit are stored as a function of the determined data in the database and also used for following comparisons.

4. The method as claimed in claim 1, wherein the high-resolution digital camera has a minimum resolution of 25 to 350 megapixels and an image sensor of at least 24×36 mm or at least a medium-format or full-format sensor.

5. The method as claimed in claim 1, wherein the high-resolution digital camera has a harmonizing double mechanical or electrical or mechanical-electronic coupled image stabilization in each case in the camera and in the lens.

6. The method as claimed in claim 1, wherein a data transmission takes place to a ground station or to the energy supplier as a live transmission by means of satellite telephone or mobile radio, wherein the data transmission with respect to recognized faults or deficiencies takes place linked with position data and image data to the energy supplier and contains a ranking with respect to a severity of an event.

7. The method as claimed in claim 1, wherein the laser scanning system, the cameras, and the sensor system are coupled to a universal measurement antenna, by means of which the combined signals of the satellite navigation system are received, which is followed by splitting of the combined signals into signal data required for a respective processing process.

8. The method as claimed in claim 1, wherein the laser scanning system acquires the data in the 360° full circle all around in the vertical and thus generates a high-resolution 3D depiction of current-carrying infrastructure having an accuracy in the millimeter range.

9. The method as claimed in claim 1, wherein the image data are generated using four digital cameras, which are attached on the aircraft so that the image data are recorded diagonally to the front and to the rear in the flight direction and once in each case downward in the direction of the ground.

10. The method as claimed in claim 1, wherein the aircraft performs the data acquisition for monitoring the operating states of the overhead power line systems at a flight speed in the range of 0 to 60 km/h.

11. The method as claimed in claim 1, wherein the aircraft flies at a distance of 1 to 50 m from the overhead power line system.

12. The method as claimed in claim 1, wherein the aircraft additionally has a radar system for determining operating states and outage probabilities, the data of which are matched with those of the sensor system, the digital camera, the laser scanning system, and the satellite navigation system.

13. The method as claimed in claim 1, wherein faults and/or defects on the current-carrying overhead power line systems causing disturbances in the electromagnetic field are measured by means of a further sensor system connected to a measuring apparatus, in particular using a selective radiation meter.

14. The method as claimed in claim 13, wherein the faults and/or defects are measured using thermal, IR, corona, or daylight sensors.

15. The method as claimed in claim 13, wherein the disturbances and/or defects are acquired as disturbances or changes in the electromagnetic field by means of antennas or antenna bundles and recorded, wherein a disturbance signal of disturbances and/or defects is tracked automatically in the horizontal and/or vertical direction.

16. An aircraft for carrying out the method as claimed in claim 1, wherein a sensor system for acquiring faults, deficiencies, operating states, and material states on overhead power line systems, a plurality of high-resolution digital cameras for image data of the systems, and a high-resolution laser scanning system are provided on and/or in the aircraft, wherein the sensor system, the digital camera, and the laser scanning system are attached in mounting units and a data processing unit is provided in the aircraft.

17. The aircraft as claimed in claim 16, wherein the sensor system is installed having ultraviolet and infrared sensors and a position sensor, multiple high-resolution digital cameras having a minimum resolution of 25 to 350 megapixels having image stabilization of camera and lens, and a high-resolution laser scanning system having 360° full circle all around in the vertical and having a resolution in the range of approximately 1500 pixels/m².

18. The aircraft as claimed in claim 17, wherein the sensor system and the laser scanning system are coupled to a universal measurement antenna, via which the combined signals of the satellite navigation system, except for GPS, are receivable and, after reception, the splitting thereof takes place into signal data required for a respective processing process.

19. The aircraft as claimed in claim 16, wherein an additional radar system is installed.

20. The aircraft as claimed in claim 16, wherein the aircraft is a manned rotary wing aircraft.

21. The aircraft as claimed in claim 16, wherein a measuring apparatus fed by a further sensor system makes the faults, deficiencies, and/or defects on the current-carrying overhead power line systems, which cause disturbances in the electromagnetic field, audible by means of an audio device and visible by means of an imaging element and stores them in a processing unit.
